(19) United States
(12) Patent Application Publication
(10) Pub. No.: US 2010/0037182 A1
(43) Pub. Date: Feb. 11, 2010

(54) USER INTERFACE FOR DISPLAYING MRI IMAGES

(76) Inventors: Eugenio Biglieri, Alessandria (IT); Luigi Satragno, Genova (IT)

Correspondence Address: BUCHANAN, INGERSOLL & ROONEY PC, POST OFFICE BOX 1404, ALEXANDRIA, VA, 22313-1404, US

(21) Appl. No.: 12/376,521

(22) PCT Filed: Aug. 1, 2007
(86) PCT No.: PCT/EP07/57990

§ 371 Date: Apr. 8, 2009

(30) Foreign Application Priority Data
Sep. 29, 2006 (EP) 06121571.1

(51) Int. Cl. G06F 3/048; G01R 33/48

(52) U.S. Cl. 715/849; 324/309

(57) ABSTRACT

Method for displaying MRI images including the following steps: displaying a plurality of different images one after the other obtained by nuclear magnetic resonance image acquisition, each of which images is different with respect to at least a part of the other images due to the fact that the plane of the displayed image corresponds to a different section plane through a body or part thereof under examination having a predetermined different position and/or a predetermined different orientation with respect to the body under examination and to a reference system; and the passage from displaying an image to display a further image is achieved by control means which define the position and/or orientation of different section planes of different images.

### TECHNICAL FIELD

The present invention relates to a method for displaying MRI images comprising the steps of displaying a plurality of different images one after the other obtained by nuclear magnetic resonance image acquisition, each of which images is different with respect to at least a part of the other images due to the fact that the plane of the displayed image corresponds to a different section plane through a body or part thereof under examination having a predetermined different position and/or a predetermined different orientation with respect to a reference system.

### BACKGROUND OF THE INVENTION

Methods for acquiring and displaying MRI images according to what is described above are known. Generally when MRI images of bodies or body parts under examination are acquired, at least a panoramic image is generated on the basis of which it is possible to choose section planes along which additional MRI images can be acquired. That is carried out thanks to means inputting commands allowing translation or rotation of the section plane along which the image is desired to be displayed with respect to the section plane of the reference panoramic image.

It is also known to generate various reference panoramic images according to section planes of the body or body part under examination which section planes for reference panoramic images are not parallel and preferably orthogonal one with respect to the other.

One of the advantages of the MRI technique for acquiring images is the fact that this technique is quite simple, i.e. by suitably setting encoding gradients, it allows acquisition of image data relevant not only to a slice or any section plane of the body under examination or part thereof, but deriving from a predetermined three-dimensional region, such that the scan provides image data in order to reconstruct a two-dimensional image along any section plane of the body under examination, that is of the three-dimensional part of said body really reproduced in acquired image data.

In addition to that it is also known that by changing some parameters acquiring resonance signals and/or by using different methods for processing resonance signals, it is possible to generate image data whose informative content is different particularly as regards the ability of highlighting or showing different types of structures or materials or tissues of which the region reproduced in the acquired image is made. So, for example, along the same section plane it is possible to acquire different information regarding present tissues by different scanning sequences. In the technical field the most known and diffuse sequences have particular names, such as for example T1, T2, fat suppression, angio, etc.

At present the selection of one or more section planes for further MRI images or the selection of one or more image data sets acquired or processed according to different modes occurs by quite complex means making selection operations quite long and little instinctive.

Particularly when a three-dimensional image of a body under examination or of a part thereof is acquired instead of two-dimensional images, current modes for selecting section planes for two-dimensional images are too long and complex and little instinctive.

### SUMMARY

Therefore the invention aims at providing a method for displaying MRI images allowing to generate a sensation of a natural or nearly natural movement of the user inside a body part under examination and especially to give the user the impression of naturally travelling or moving like an observer inside a three-dimensional part of a body under examination of which the three-dimensional image has been acquired.

The invention attains the above aims by providing a method of the type described hereinbefore wherein the passage from displaying an image to display a further image that is different as regards position and orientation of the section plane along which the image is generated is achieved by control means generating commands which define parameters describing the position and/or orientation of different section planes of different images by means of signals for angularly moving or displacing or translating in one of various directions the section plane from a starting reference position.

According to a variant of the present invention, which variant can be provided as an alternative or in combination with the above embodiment, each one of the displayed images is different with respect to the others due to the fact that image data for generating at least a part of the images are acquired with different modes or are obtained with different processing or computation methods with respect to image data of further images, wherein the passage from displaying an image to displaying a further image that is different as regards the mode for acquiring or processing image data is achieved by control means generating commands which define parameters describing the image data set acquired according to one of the said various different modes and/or processed according to one of the said various different processing methods and which commands are constituted by signals selecting and addressing and/or calling up image data from different image data sets each one of which sets corresponds to image data acquired or processed according to one of various different acquiring and/or processing modes.

Therefore the idea of the present invention is to give the user the possibility of travelling inside a body under examination or a part of the body under examination by offering the user sight the scene or the image that he approximately would see by turning his eyes in various directions or by offering the user what he will see in a certain direction if he has alternatively visual sensors having different types of sensitivity.

Therefore, there are two travelling modes and they include one hand just in the topologic one and from the other hand in the one relevant to the detectable visual information.

Therefore the user can move inside an image as he would move inside the body under examination.

The topologic or geographic mode, in its most basic form, may be a method for displaying MRI images wherein the following steps are provided:

Acquiring by means of a MRI scanner at least a two-dimensional MRI image according to at least a section plane of a body or a part of the body to be examined and displaying said MRI image;

defining at least a reference direction having a predetermined orientation with respect to said MRI image and displaying said direction on the MRI image displayed at the previous step;

defining a movement of the section plane along a direction having a predetermined orientation with respect to said at least one reference direction;

acquiring and displaying one or more further MRI images along section planes translated and/or rotated with respect to the section plane of a first MRI image or of a preceding MRI image according to said at least one moving direction.

The selecting command is generated by commands advancing the translation of the section plane forward or backward with reference to a reference section plane and commands rotating the section plane forward and backward with respect to a predetermined reference section plane, which commands are generated and inputted by directional control interfaces of everyday use.

Particularly the invention provides such means for inputting commands translating and rotating the section plane to be composed of button means and/or pivotting lever means of the joystick type and/or pointers of the type known as mouse or trackballs, or the like and/or commands composed of particular keys or combinations of keys of a keyboard and which keys or which combinations of keys are associated to a predetermined univocal command.

Advantageously the method provides to set a minimum step for moving and/or rotating the section plane with respect to a reference plane each operation of button means and/or each pivotal movement and/or rotation of the lever of the joystick being associated to forward or backward movement and/or to the rotation in one direction or in the opposite direction only of a step of the section plane with respect to the section reference plane. The repeated operation of a button and/or of the lever of the joystick causes the forward and/or backward movement and/or the rotation in one direction and in the other one of a further step of the section plane.

Advantageously it is also possible to provide for the continuous operation, such as the continuous pushing of a button and/or the continuous pivotal movement of the lever of the joystick to determine a sequence of forward and/or backward movement steps or rotation steps in one direction or in the other one.

According to a variant particularly to be used with a joystick it is possible to correlate the tilt angle of the joystick with respect to a neutral position with a scale of forward and/or backward and/or rotating movement in one direction or in the other one of the section plane, which scale can be modified depending on the tilt angle of the joystick lever with reference both to the minimum distance step of section planes and/or to the minimum angle of rotation of section planes and with reference also to the rate at which the display passes, i.e. at which images regarding individual section planes move on the displaying screen.

Particularly when three-dimensional images are used, the method provides to translate and/or rotate the section plane and to generate and display the corresponding image along said section plane on the basis of image data of the three-dimensional image provided along a section plane having a corresponding orientation with respect to the three-dimensional image.

By the fact of having three-dimensional image data, and defining a reference coordinate system in common to the three-dimensional image and to means for translating and/or rotating the section plane along which an image has to be displayed it is possible to determine image data referring to image voxels falling on a virtual section plane of the three-dimensional image corresponding to a section plane selected by directional control means for said section plane and so it is possible to generate the two-dimensional image along the selected section plane from data of the volumetric image.

Advantageously, in order to make easier the selection of the section plane it is possible to display a three-dimensional image on the displaying monitor in combination with the reference coordinate system and in combination with the image of the selected section plane and the relevant orientation with respect to the three-dimensional image. The three-dimensional image displayed on the monitor is simply a projection of the three-dimensional image on a two-dimensional plane for example an axonometric or perspective projection.

For each change in the position of the section plane both regarding a translation and regarding a rotation it is possible to display both the new position and the new orientation of the section plane with reference to the three-dimensional image and the translation direction or the rotation direction.

A further improvement of the method and of the apparatus which allows to obtain a natural navigation experience for the viewing person simulating a real navigation experience may further provide that at least three screens are provided one being in a central position between two lateral screens, the central screen being the one on which the images on different section planes perpendicular to a defined direction of displacement or of forward or rearward navigation are displayed, while on the two lateral screens which are oriented at an angle with respect to the central screen and symmetrically relatively to a centre section plane perpendicular to the said central screen images are displayed along section planes whose angle relatively to the section plane of the image displayed on the central screen corresponds to the angle of corresponding the lateral screen relative to the central screen.

The three screens may be substituted by a panoramic arched screen in which focus or center of the curvature of the arch is from where the person viewing is standing and which screen has different areas on which the images of the different oriented section planes are visualized having a tangent orientation to a certain reference point or line of the corresponding area.

As a further improvement, the system automatically determines the section planes of the lateral images to be displayed on the two lateral screens or on the two lateral areas of the arched screen and which section planes of the lateral images are at a certain angle, particularly perpendicular to a section plane which is oriented perpendicular to the direction of view and which corresponding image is displayed at the central frontal area or at the center frontal screen and the system automatically determines the new section planes of the lateral images each time the section plane of the frontal image is changed due to displacement in a forward or rearward direction of the section plane of the image to be displayed on the frontal, central screen, i.e. of the section plane perpendicular to the direction of view.

This particular embodiment gives a more realistic view or navigation effect. The said embodiment is very simply realized when the image acquired is a three dimensional image which is defined by three dimensional image data. Here defining a reference system for the position and orientation of the section planes and choosing a section plane in the image along which it is to be displayed on the frontal, central screen the determination of the section planes for the lateral images to be displayed on the lateral screens or on the lateral screen areas can be made by selecting an angle between each lateral section plane and the central frontal plane which can be also the angle between the central screen and the lateral screens.

According to a further advantageous characteristic of the invention, the system provides to carry out the above steps in combination with an exploratory preventive scan that, due to the travelling steps described above, with reference to a main scan, allows one to find with a great precision, for example, a partial region or a section plane at which a scan can be carried out with scanning parameters typical for main scans and so intended to provide data allowing to generate images with a greater quality however against a longer length of time of the scan i.e. of the image data acquisition.

To this aim, therefore it is possible for scanning sequences, i.e. parameters acquiring image data during said preventive exploratory scan, to be set such that they require short lengths of time for acquiring and generating images, to the detriment of the quality of image data and of relevant images. So for example it is possible to reduce the resolution or contrasts of the image or to avoid acquisition devices meant to optimize the signal-to-noise ratio and to limit the danger of generating artifacts to the detriment of the acquisition rate.

Therefore by means of an exploratory preventive scan of the above type, the invention in a short time allows one to acquire images particularly volumetric ones, i.e. 3D ones, of a body under examination or part thereof, and to travel inside said volume, generating views of two-dimensional images that a user would see inside the virtual world composed of three-dimensional image data by turning his eyes in a specific direction, at a great speed, allowing one at the same time to identify regions of the body under examination corresponding to partial regions of the whole acquired volume and about which it is possible to carry out in a precise way more in-depth and detailed acquisition of image data with longer scanning sequences.

The second displaying mode that can be provided in combination with or separately from the one previously described, for the same body part provides a plurality of image data acquired according to different modes i.e. according to different settings of acquiring parameters or of so called acquiring or scanning sequences and by which different characteristics of the body under examination, particularly of tissues thereof are highlighted. As an alternative to the change of settings of acquiring or scanning parameters, when it is possible, the invention provides also to determine different image data sets from at least a single image data set acquired at the beginning according to a predetermined acquiring mode by means of operations computing or mathematically processing image data acquired at the beginning.

In this case, in a first embodiment, by means of control means, the invention provides to pass from the image along a predetermined section plane relevant to image data acquired according to a predetermined mode or obtained by a predetermined computation or processing method to one or more subsequent images along the same section plane and relevant to image data acquired according to one or more further acquiring modes or one or more further modes for computing or processing image data.

Moreover according to an improvement it is possible to combine this travelling or navigation mode allowing to display a sequence of images generated by image data acquired according to different modes acquiring images or processing image data with the geographical or topologic travelling mode previously described and allowing to display a sequence of images each one generated along a predetermined section plane that is or can be different with respect to the section plane of other images of the sequence.

According to a preferred embodiment, the method provides to acquire 3D (=three-dimensional) or 2D (=two-dimensional) images of the same body under examination or of the same region or part of the body under examination, with different kinds of acquiring sequences such as the known sequences called T1 and T2, sequences known as fat suppression, angio, and with other kinds of sequences, and the alternative display on a monitor of the image relevant to the same section plane, with reference to the acquired three-dimensional image or with reference to a plurality of two-dimensional images acquired with the different sequences, of said image obtained with the different kinds of scanning sequences and that is above mentioned sequences T1, T2, fat suppression, angio, etc.

As an alternative and when it is possible, image data relevant to different kinds of scanning parameters can be simply computed from an image data set acquired with a single common scanning sequence, by mathematically computing and/or processing said image data or corresponding electromagnetic signals.

The passage from the display of the image along the same scanning plane obtained with different kinds of image data can occur by the command obtained with means similar to the ones used for passing the image display from one scanning plane to a different scanning plane described above.

In this case, it is possible to provide control means such as a switch button that modifies the command generated by control means, such as a joystick, mouse, trackball or also keyboard commands into a command intended to display the image according to a predetermined different scanning plane and a command intended to display the image of a scanning plane according to a predetermined scanning sequence.

As regards different scanning or acquiring sequences for image data they are widely known and widely used.

T1 and T2 are biological parameters and the former indicates the relaxation time constant in the direction of z-axis called spin-lattice relaxation time, whereas the latter parameter indicates the spin-spin relaxation time in the plane defined by the xy axis. The material of which different biological tissues are made has different T1 and T2 parameters. So by using suitable exciting sequences herein referred to as scanning or acquiring sequences for image data, it is possible to generate signals corresponding to image data highlighting the behaviour of the tissue with reference to T1 and T2 parameter and so to highlight different kinds of signals. Similarly it is possible to combine MRI scanning signals such that they are relevant to a combination of T1 and T2 parameters that is suitably weighted in order to highlight specific kinds of tissues.

A more precise description of scanning sequences can be obtained in the document: Quaderni Di RM 1, “Basi fisiche della Risonanza Magnetica” of A. Desgrez, J. Bittoun, I. I D Y Peretti, Masson S. p. A., Milano 1992.

Therefore a specific embodiment of the method according to the present invention comprises in detail the following steps:

a) generating by computation from three-dimensional or two-dimensional image data obtained by a single scan or a limited number of scans with different scanning sequences a plurality of different image data sets or acquiring a plurality of different image data sets each one by a scan with a different scanning sequence;

b) storing said image data each one in a dedicated memory or in a dedicated memory area;

c) associating an identification code to each image datum of each image data set;

d) associating an identification code to each image data set computed or acquired with a different scanning sequence;

generating a command for calling up from the corresponding memory or memory area a single image datum and/or image data along a predetermined image plane and for displaying on a monitor the called up image datum or image data, which command comprises a univocal identification code of the memory area wherein the image data set is stored from which the image datum or data are called up and an univocal identification code of the image datum or data within said image data set;

generating one or more different call-up commands one after the other for calling up from the same memory area or from different memory areas a single image datum and/or image data along the same predetermined image plane or along a different image plane and for displaying on a monitor the image datum or image data called up with each subsequent command, which command comprises a univocal identification code of the memory area wherein each different respective image data set is stored from which the image datum or data are called up and a univocal identification code of the image datum or data within each one of said image data sets.

As already pointed out above the system according to the present invention allows two different modes for travelling in image data which can be carried out alternatively or in combination one with the other. A mode includes changing the image plane, i.e. the section plane of the body under examination or a part thereof towards which the user ideally turns his eyes, the direction of sight being defined by control means described above and the selected section plane being defined with a section plane having a predetermined orientation with respect to an axis representing the direction of sight and that is defined by control means. A second mode, once a section plane along which the image of the body under examination or part thereof has to be generated is chosen, allows to change the displayed image correspondingly to different modes for acquiring image data and/or processing said image data.

The combination of these two travelling modes allows to change both the section plane along which the image is generated also called image or scanning plane and/or the selection of image data according to different scanning and/or processing modes.

As regards the definition of individual image data it has to be noted that for the person skilled in the art the concept according to which said data are in the form of arrays of two-dimensional and three-dimensional data is clear depending on the fact if it is a two-dimensional or three-dimensional image and wherein each element of the data array univocally represents the position and the appearance of the corresponding pixel or voxel.

Since the image is displayed on a monitor by means of a physical two-dimensional pixel array, once a scanning or image plane is chosen, the orientation of said plane is univocally determined with reference to the three-dimensional image data set and as image data to be called up the ones falling or closer to the section plane are defined.

For guaranteeing a univocal and right relation between individual image data sets and a directional reference system, for example a three-dimensional system of Cartesian coordinates, it is advantageous to provide also a step registering the different image data sets with a predetermined reference system, for example said Cartesian axis system. The registration is useful also for positioning in the proper topologic relation image data sets acquired with different scanning modes. That allows one to have the subject of the image as substantially fixed when there is the passage from the display of the same image plane according to an acquiring mode to the one according to at least a further acquiring mode.

As regards the registration of image data in the form of array structure sets of both two-dimensional and three-dimensional image data there are different techniques. A particularly advantageous technique is described in the document

1. Sorzano C O, Thevenaz P, Unser M. Elastic registration of biological images using vector-spline regularization. IEEE Trans Med Imaging 2005; 52:652-663

2. Crum W R, Hartkens T, Hill D L. Non-rigid image registration: theory and practice. Br J Radiol 2004; 77 Spec No 2:S140-53

3. Park H, Bland P R, Brook K K, Meyer C R. Adaptive registration using local information measures. Med Image Anal 2004; 8:465-473.

4. Kim J, Fessler J A. Intensity-based image registration using robust correlation coefficients. IEEE Trans Med Imaging 2004; 23:1430-1444

5. Pluim J P, Fitzpatrick 3M. Image registration. IEEE Trans Med Imaging 2003; 22:1341-1343

and in further documents mentioned in said documents.

Finally still according to a further variant of the method described above, it is possible to provide the storage according to the right time succession of all images displayed along different section planes selected during the travelling process and/or all images corresponding to image data processed according to different modes for processing resonance signals and/or obtained by different acquiring modes said stored image sequence can be called up and displayed in the right image time succession.

In this case it is possible to change the so called frame rate that is the speed of the passage from an image to the following image also in a diversified manner for individual different images of the sequence or for sub-groups of said images. Thus the travelling in an image data set displayed with a predetermined two-dimensional image sequence according to different directions of sight and/or according to different modes for acquiring or processing image data are reproduced as a kind of film.

According to a further advantageous characteristic that can be provided as an alternative or in combination with characteristics previously described, the invention provides image data of each acquired image to be changed as regards the visual appearance of the corresponding image displayed in a view similar to the one occurring by using an endoscopic instrument.

Images, obtained by the above processing method are re-processed in a virtual three-dimensional scene, wherein the user can travel by “moving” inside interstitial spaces and “watching” surfaces of organs he meets in the path. This display follows the purely arthroscopic one, obtained by the orthopedist by inserting an optical visual probe inside the limb. Therefore such display is more “user friendly” and allows the optimal exchange of information between the radiologist carrying out the examination and the orthopedist, guaranteeing the greatest efficacy in treating the patient. The consignment of the diagnosis can be supplemented by a film, reconstructed starting from MRI images, that will show to the orthopedist the position of the pathology and it can be the optimal base for planning the operation.

The fact of allowing the clinician, principally the orthopedist, to have a mode for displaying 3D data similar to the arthroscopic one in short leads to a more effective interaction between the radiologist and the clinician, allowing him to reach a better understanding degree of the diagnostic result obtained by the radiologist, all to the patient advantage.

The invention relates also to an apparatus for acquiring and displaying MRI images and having means for acquiring and generating image data, at least a memory for storing image data; means for selecting a section plane along which a MRI image can be acquired and displayed and means for displaying said MRI image along said section plane.

According to the invention, means for selecting and changing the section plane along which the MRI image is acquired are composed of one or more buttons for commanding the translation in the forward direction and in the opposite backward direction and/or one or more buttons for commanding the rotation of the section plane in one direction and in the opposite direction.

Alternatively said selecting means may be a joystick, a trackball, a so called joypad or keyboard controls including combinations of keys or the like.

Means for selecting and changing the section plane have means for interfacing the command moving forward and/or backward and/or rotating the section plane in one direction or in the opposite one to units setting the imaging section plane of the MRI scanner.

Still according to a further characteristic the apparatus comprises a plurality of means for acquiring magnetic resonance signals according to different acquiring modes, particularly according to different sequences acquiring magnetic resonance signals, and/or different means for generating image data from magnetic resonance signals according to different modes processing said magnetic resonance signals;

means for separately storing each set of magnetic resonance signals or each image data set obtained by each one of the different modes acquiring magnetic resonance signals and/or according to each of the different modes processing said magnetic resonance signals;

means for univocally identifying said sets of magnetic resonance signals or said image data sets;

means for selecting one of said different sets of magnetic resonance signals and/or said different image data sets;

commands means for calling up from the corresponding memory and for displaying the selected set of magnetic resonance signals or image data set;

means for changing the selection of the set of resonance magnetic signals or the image data set being provided.

Above selecting means, said call up command means and said means for changing the selection of a predetermined set of magnetic resonance signals and/or a predetermined image data set are provided in combination with selecting means, means for changing the selection of a section plane along which an MRI image can be acquired and display.

According to a variant, the MRI scanner has means for acquiring magnetic resonance signals and for generating three-dimensional image data, i.e. relevant to a three-dimensional region of the body under examination. Said image data describing the appearance of each voxel of the three-dimensional image are stored in a memory, means for selecting the section plane and for changing it being provided with means interfacing a reading unit for image data relevant to voxels of the three-dimensional image that coincide with a virtual section plane of the three-dimensional image within a predetermined tolerance.

As regards the above reading unit it is clear that a digital three-dimensional image i.e. composed of a voxel set as regards numerical data corresponds to a three-dimensional array of numerical data constituting parameters describing the appearance of each voxel. Topographic relations between individual voxels may be kept in a memory by suitably managing memory addresses, so by defining a reference spatial coordinate system the latter may be associated to the three-dimensional image data set and for each section plane individual memory areas can be identified whose addresses correspond to the orientation of a virtual section plane of the three-dimensional image that is parallel or substantially coinciding with the selected one.

When the position or orientation of the section plane are such to fall between two voxels the appearance of the pixel of the two-dimensional image along said section plane is determined for example by means of an interpolation between values of the two voxels between which the selected section plane passes.

Thanks to the above characteristics of the method and of the apparatus according to the invention the user can travel very easy and simply along a body or a part thereof under examination. The selection of the direction where images can be acquired and of the plane along which images can be acquired is completely intuitive and quick such as a process for travelling or directionally controlling a vehicle.

The further display of one or more reference two-dimensional images and/or or a two-dimensional axonometric or perspective projection of the three-dimensional image and the indication on said images of the position and orientation of the section plane that is selected each time, as well as the indication of the translating or rotating direction of the section plane allow always to have a clear quick glance view of the body region under examination of which the image is displayed and of the section plane along which said image is acquired and displayed with reference to the body under examination.

It is to be noted that by the improvement of techniques acquiring images particularly MRI ones the travelling inside a body under examination it is possible in real time allowing the doctor to identify and/or search possible lesions or pathologies of which the patient has symptoms. So the doctor can easily identify the region suffering from the pathology and he can change quickly and intuitively the point of view.

As regards the mode displaying image sequences generated during a travelling session in image data of the cinematographic type, the apparatus can provide a separated memory for storing all selected and called up images in a predetermined image sequence and/or also as an alternative simply a memory of commands selecting and calling up image data for each of the selected and called up two-dimensional views and a command associating said images according to a specific time order, as well as means for selecting and/or changing the speed at which the image sequence is reproduced.

### BRIEF DESCRIPTION OF THE DRAWINGS

Further advantages and characteristics of the invention will be more clear from the following description of a not limitative embodiment shown in annexed drawings, wherein:

FIG. 1 schematically shows the method selecting section or image planes along which MRI images to be displayed according to the present invention are selected.

FIG. 2 is a block diagram of an example of an apparatus for acquiring and displaying MRI images according to the method of the present invention.

FIG. 3 is a block diagram of an alternative method selecting and displaying MRI images according to the present invention.

FIG. 4 is an example of a displaying screen.

FIG. 5 is an example of the apparatus relevant to the method according to FIG. 3.

FIG. 6 is a block diagram of steps displaying image data acquired in the form of a view simulating an endoscopic examination and particularly an arthroscophic one.

### DETAILED DESCRIPTION OF THE PREFERRED EMBODIMENTS

While said method and apparatus are described with reference to a preferred embodiment providing the acquisition of a three-dimensional image of a body or part thereof under examination, the invention has not to be considered as limited to this embodiment the method being possible to be applied also to acquisition of two-dimensional MRI images, in this case each time a command translating and/or rotating the section plane along which an image is desired to be displayed is inputted the apparatus will provide to set parameters acquiring images along said selected section plane and to acquire the image along said section plane, in this case there being possible also to store individual images, as well as their position and relative orientation.

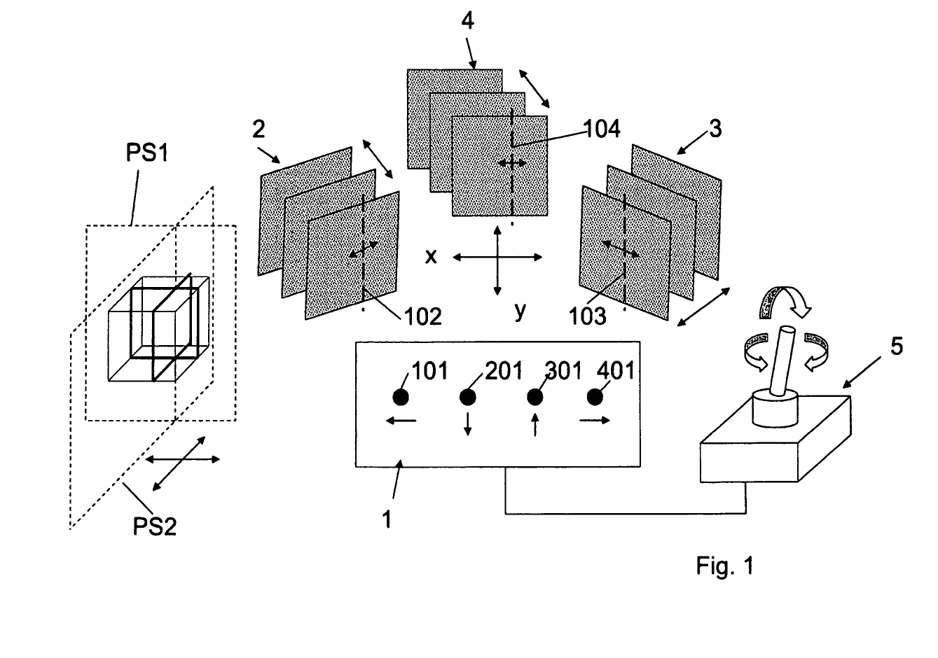

Referring to FIG. 1, there are shown two different types of means for inputting directional commands translating and/or rotating the section plane. A directional control console is indicated by 1 provided with buttons 101, 201, 301, 401. To each button there is assigned a command for the directional movement in the direction of the arrow below each of them. For simplicity reasons movements only along two directions perpendicular one with respect to the other are indicated, Each time one of the buttons is pushed a step translating and/or rotating the section plane of the displayed and/or acquired and displayed image in the case of acquisition only of two-dimensional images one by one occurs. Side buttons 101 and 401 cause the section plane to rotate, while central buttons 201 and 301 cause a translation in the backward or forward moving direction. It is possible to provide a pushing prolonged in time to be interpreted as a translation or rotation of a certain amount of steps corresponding to the time pushing the button and with reference to predetermined time intervals. This function is known in computer keyboards for example as repeat function. Squares 2, 3 and 4 for example indicate various forward and/or backward movement conditions of the section plane according to three different orientations. In this example there is shown the sequence of images along different section planes parallely translated one with respect to the other along three directions.

Squares at sides 2 and 3 indicate sequences of images along section planes oriented parallely one with respect to the other and perpendicularly to central section planes 4 that are parallel with respect to the sheet.

In order to pass to display images along section planes corresponding to images of the sequence 2 it is possible to push the button 101 for a certain number of times or to keep it continuously pushed for a certain time period, while the translation in one direction or in the other one is obtained by central buttons 201 and 301. The sequence of images indicated by 3 is obtained by pushing the button 401 till the section plane is rotated in said position and even in this case there is the passage to the display of single images along section planes parallel one with respect to the other but translated one with respect to the other by using central keys 201 and 301. Similarly it is possible to pass from a section plane having an orientation as indicated by images 2 and 3 to the one of images indicated by 4, whereas the display and/or acquisition of images along section planes translated one with respect to the other but parallel one with respect to the other is obtained still with the two central buttons 201 and 301. The passage from an image to a subsequent one or viceversa is shown in FIG. 1 by the fact that icons representing three images are shown as staggered one with respect to the other. Section planes of images 2 and 3 are to be intended as perpendicular to the sheet and to section planes of images 4 since are shown in perspective.

An alternative to the control button console 1 can be a keyboard like the one used for computers. In this case it is possible to define some combinations of keys or some function keys such that signals generated by pressing them are interpreted like buttons of keyboard 1. As an alternative and/or in combination with push-button panels or keyboards described above it is possible to provide also different means such as a joystick 5 or an equal means such as a trackball a joypad or a simple mouse. The shown joystick has a lever that can be moved according to various spatial directions. In this case the orientation of section planes and translation thereof is operated by joystick instead of buttons.

As regards displaying it is possible to display images of different section planes having different orientations one with respect to the other on the same monitor or on various monitors.

It is also possible such as indicated by broken lines and arrows 102, 103 and 104 to display on different section planes the relative position or the line intersecting a section plane having a first orientation with a section plane having a second orientation when at least one of the images along a first section plane is kept and when the image is displayed along a section plane having a different orientation and not parallel to the section plane of the first image. When the section plane is translated parallely with respect to itself, the line intersecting the section plane of the first image is correspondingly moved on said first image.

So for example, by considering to keep active on the screen of a monitor the last image displayed along one of the section planes 4 parallel to the sheet, and by providing to display the sequence of images obtained by forwardly translating the section plane of images indicated by 2 or 3 the line 104 on said last image 4 will move correspondingly to the translation of said section planes parallel to the image 2 or 3.

Still according to a further variant that can be provided in combination with or alternatively to the preceding one it is possible to display on an area of the monitor screen an axonometric or perspective image of the body under examination or part thereof that is shown as a cube and of different section planes indicated by PS1 and PS2 and referring to orientations of section planes of images 4 and images 2 and 3 respectively.

As an alternative still keeping the panoramic image as a perspective one or in axonoinetric projection or some images along reference section planes, for example along three space directions of a system of Cartesian coordinates it is possible to display one by one the image of a section plane still replacing the preceding one with the new image along a new and different section plane. The orientation of the user with reference to the body under examination or the part thereof is however guaranteed by the perspective or axonometric projection image wherein there are shown section planes along which each time the image and orientation and relative position of said section planes are displayed with said axonometric or perspective projection of the body under examination or wherein lines intersecting the section plane with section planes of reference images are displayed.

Therefore the method according to the invention, allows to generate a kind of virtual mode for the user to travel inside a three-dimensional digital image of a body under examination or of a specific part thereof. The command for selecting the image or section plane and the display of the corresponding image generate a virtual condition wherein the user can instinctively feels as inside the body under examination or part thereof reproduced in the three-dimensional image and he can turn his eyes or the direction of his eyes in any directions due to selecting and commanding means there being displayed a two-dimensional approximation of the image that the user would have if he really was inside the image and so of the reproduced image of the body under examination, i.e. a kind of virtual condition for travelling inside the three-dimensional image.

The method described above may be used in combination with scans carried out with sequences such to obtain the best image qualities or also in combination with preventive or exploratory scans having the aim to reveal to the user the approximate conditions of regions reproduced in the image and so to reveal to him restricted size regions to be subjected to more in-depth acquiring scans.

In this case, for example MRI image acquiring sequences and further MRI image acquiring parameters may be selected in such a manner that the acquisition of the three-dimensional image or of individual two-dimensional images is quite quick to the detriment of quality, such as for example the resolution and/or the signal-to-noise ratio and/or contrast and/or artefact suppression. However the fact of travelling in the three-dimensional image has only the aim of identifying smaller regions to be subjected to a scan with such scanning sequences or parameters to guarantee a greater resolution and/or greater contrast and/or a better signal-to-noise ratio and/or a lower generation of artefacts or with such sequences and parameters to highlight specific structures or specific kinds of tissues whose presence is suspected or detected with a certain probability on the basis of the preventive and exploratory scan.

Above means for selecting the scanning or image plane are known means and are widely used in combination with modern computers, such as personal computers or the like. As it will be noted below a lot of functionalities of MRI apparati are obtained by a hardware of the type similar to the one of a computer also of the commercial available type wherein specific programs for carrying out specific tasks for the MRI apparatus or for commanding a further specific hardware are loaded. General directions for a construction of this type for example are included in document U.S. Pat. No. 6,720,770.

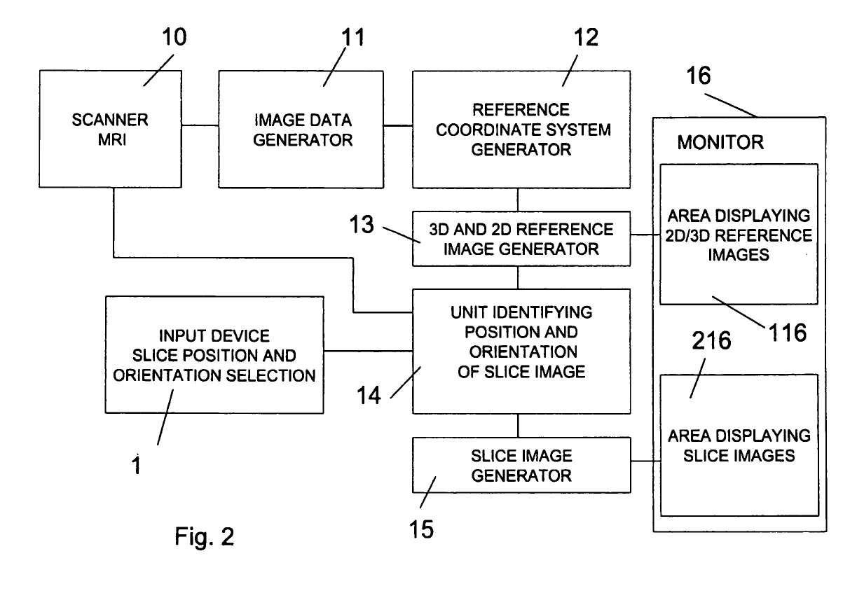

FIG. 2 shows the block diagram of an embodiment of an apparatus for acquiring and displaying images working according to the method of the present invention.

Particularly it is an apparatus for acquiring and displaying MRI images.

A general MRI scanner for acquiring both two-dimensional and three-dimensional images is indicated by 10. Signals obtained by the scanner are provided to an image data generator 11 from receiving signals. In a MRI apparatus these signals are electromagnetic signals generated by the magnetic resonance effect of protons that once subjected to excitation by electromagnetic energy irradiation they again give part of said energy as electromagnetic pulses. In the present description and in claims the above said signals are briefly called magnetic resonance signals or simply resonance signals.

By means of a suitable coding by aligning spins by a static magnetic field and by means of the univocal topologic identification coding of sources of individual resonance signals obtained by magnetic gradients applied for selecting a predetermined image plane i.e. a portion (slice) or a section plane of the body under examination and within which the topologic correlation between signal contribution and position of the source within the section or scanning or image plane it is possible to generate an image of the body under examination along said scanning plane. Therefore by processing magnetic resonance signals image data are generated which are composed of two-dimensional or three-dimensional data sets, particularly array structure data sets each element of said array being intended to univocally define the appearance of a pixel of a digital monitor or a pixel set of said digital monitor, the image being formed by a pixel set as a two-dimensional array of said pixels. In this case the term pixel defines both the numerical datum or numerical data in a data set in the form of two- or three-dimensional array and a discrete unit element of the image that can take different brightness and/or colour conditions.

According to a further characteristic a virtual reference coordinate system associated to image data as indicated by 12 is further generated. Reference two-dimensional or three-dimensional images are generated from image data as already previously described. These are displayed in a special displaying area 116 of the monitor 16. By a device 1 selecting and setting directional controls for example of the type previously described a section plane is selected along which the image is desired having a predetermined orientation and a predetermined position with reference to the body under examination or a part thereof and/or to image data already acquired. Therefore the section plane called also image or scanning plane and set by directional commands 1 (called also slice in the technical language of the art) is identified as regards its position and orientation with reference to the coordinate system in a corresponding unit 14 and so the image along said slice is generated i.e. the image along the section plane selected by a generator 15 providing the monitor 16 with image data for displaying said image in a special area 216 of the screen of the monitor 16 different from the one 116 for displaying reference two-dimensional or three-dimensional images.

Referring to FIG. 2 there are shown two possible variants. When the scanner acquires a three-dimensional image, so the unit 14 identifying the position and orientation of the section plane of the image takes data of voxels or pixels falling on said section plane directly from image data provided by the image data generator 11 and by means of the reference coordinate system. That is possible, since a digital image made of a voxel set is virtually represented by the three-dimensional array of image data relevant to said voxels and by using memory area addressing systems both for storing image data and for reading them it is clearly possible to maintain and univocally identify image data of each voxel and its position. Therefore once the section plane is defined it is possible to determine which voxels and relevant image data fall on said section plane by applying the right law computing memory addresses.

On the contrary when the scanner acquires only two-dimensional images, the unit 14 identifying the position and orientation of the section plane of the image provides the scanner with parameters selecting the section plane along which the image has to be acquired according to the selection made by directional control means and the corresponding slice image is acquired and therefore sent to the slice image generator 15.

The unit identifying the position and the orientation of the image section plane is also able to generate images of lines intersecting individual section planes along which different slice images are generated with section planes of reference two-dimensional or three-dimensional images on reference panoramic two-dimensional or three-dimensional images also indicating by arrows the direction of the section plane moving from a first image to a second image.

From FIG. 2 it is clear that the apparatus may be composed of a computer wherein programs are loaded for executing different described tasks and for controlling the MRI scanner as well as for managing memories wherein magnetic resonance signals are stored, for executing processes for processing said signals for generating image data.

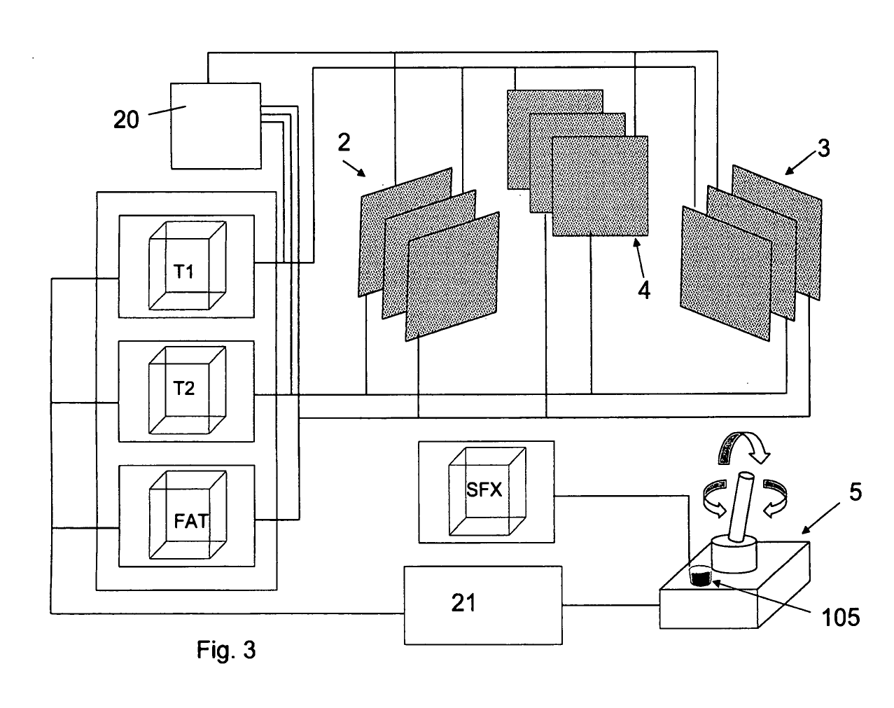

FIG. 3 shows an alternative travelling mode according to the method of the present invention that can be carried out alternatively to the one previously described or also in combination with said first mode described above.

It is generally known that by means of different settings for acquiring MRI images or by means of different modes processing resonance signals it is possible to obtain different information, that is it is possible to identify or to highlight specific kinds of tissues or structures. As already described in the introduction part, it is possible to acquire MRI images by different kinds of scanning sequences that are known for a long time and that in the language of the art are indicated as T1, T2, fat suppression, angio and other ones.

Along the same section or image plane, therefore it is possible to obtain different image data sets that make different kinds of structures, tissues or objects reproduced in the image as visible or recognizable ones depending on the mode acquiring and/or the mode processing resonance signals for obtaining image data.

In the case of a two-dimensional MRI image it is therefore possible to display various images having a different informative visual contents, depending on the kind of image acquiring sequence and/or the processing type for resonance signals. Therefore there are two different choices by which it is possible to obtain different image data sets each one of which sets has a different informative contents and consisting in the fact of using different settings for acquiring the image and i.e. different sequences or alternatively of using different processing processes for determining image data from resonance signals taken when scanning.

The two choices may be also combined one with the other.

In FIG. 3 for simplicity reasons there are shown three different image data sets indicated by T1, T2 and fat suppression and they have to be considered both as the result of three different scans with optimized scanning sequences for obtaining each one of the three data sets, and as the result of three different processes processing resonance signals of a single common scanning process.

Image data sets are three-dimensional sets. They are represented by three-dimensional arrays of image data, that are graphically represented in FIG. 3 by a parallelepiped in axonometric view. Each one of the three-dimensional arrays of image data univocally associates a datum or a data string to a position of said datum or said data string within the three-dimensional array and each position in the three-dimensional array corresponds to a position of a unit image element of the three-dimensional image or of the two-dimensional image along a section or image plane containing said element. The image datum or the image data string provided in a predetermined position in the three-dimensional array composing image data determines the visual appearance of the corresponding unit image element that in three-dimensional images is called voxel and in two-dimensional images on the contrary is called pixel.

Therefore there is both a direct topologic relation between position in the three-dimensional array of an image datum or of an image data string and position of the corresponding unit image element in the image and between image data values and the appearance of unit image elements so the image data set in the form of a numerical array corresponds to or it is a different representation of the visual image.

In the example according to FIG. 3, the joystick 5 or any other devices among the ones described as an alternative with reference to the previous example may be used to change the displayed image not with respect to the section or image plane corresponding to a different sight or watching direction, but with respect to the kind of the image datum with reference to the acquiring mode, i.e. with reference to the particular acquiring sequence and/or with reference to the mode processing resonance signals, i.e. the specific process processing said resonance signals.

Therefore depending on the movement of the joystick lever it is possible to display along the same section or image plane the same image but obtained from different image data that is from image data deriving from different acquiring sequences and/or different processes processing resonance signals.

As already said in the previous example, as an alternative to the joystick it is possible to use different selecting and control devices that can be a keyboard of special type or a common computer keyboard whose keys or combinations of keys have been defined in order to be interpreted as selecting and displaying commands; a trackball, a joypad, a simple pc mouse, or the like.

Different parallelograms 2, 3 and 4 that are shown as staggered ones and that are connected to different image data sets T1, T2 and fat suppression schematically show the fact that the operation of the joystick or other control means generates the passage from an image generated on the basis of image data of a set to one or more subsequent images on the contrary generated on the basis of image data of one or more further image data sets.

What has been described above is referred to a travelling mode limited to the second choice. However the second travelling mode that can be obtained by the system according to the present invention may be combined with the travelling mode described with reference to FIGS. 1 and 2.

In this case, as indicated by PSX data set, it is possible to change both the section or image plane along which the image is displayed, and to choose the image data set falling on said section or image plane and which determine the visual appearance and the visual information of the image as described with reference to FIG. 3.

In this case, the example of FIG. 3 provides the fact that the very joystick may be used for selecting and displaying the corresponding image both as regards the change of the displayed section or image plane and as regards the image data set, by control means commuting the joystick task which can be of any type and which are represented by a general button 105 in the schematic example of FIG. 3.

Alternatively it is possible to provide two separated selecting and control means, such as two joysticks, a keyboard with various buttons for various travelling modes and/or other devices among the ones already described above.

According to said travelling combined mode, by acting on the switch 105 it is therefore possible to select a section or image plane that such as described in the example according to FIGS. 1 and 2 is defined by the three-dimensional set SPX whose elements may be composed only of placeholder elements to determine which are the positions in three-dimensional data sets that fall in the section or image plane. Once the section or image plane has been selected and once positions in the structure of the three-dimensional array of elements falling in the section or image plane have been defined, said elements or better the positions thereof are univocally defined by series of three indexes that are stored and joint to the command string generated by the joystick 5 in the switch condition of the switch 105 enabling said joystick to the selection of the image data set T1, T2 or fat suppression. In this case, elements of the selected image data set will be read and called up and therefore displayed in the image generated on the monitor, whose indexes, i.e. whose positions correspond to the stored ones i.e. of the elements of the three-dimensional structure of the array falling in the section or image plane.

During the combined travelling, by acting on the function switch 105 it is possible to maintain the section or image plane and to change the displayed image, taking image data from a different set or such as schematically shown by image sequences 2, 3 and 4 to change the section or image plane and to maintain the image data set from which said data are taken or to change also said image data set.

Still in the example of FIG. 3 there is provided a memory indicated by 20 wherein images that have been displayed in sequence during the travelling and/or that would have been displayed are stored in the right time succession. Therefore in this case an image sequence is generated in the form of a cinematographic sequence and it can also be displayed on the monitor as a cinematographic sequence. As already said above, during travelling the image sequence had the possibility to be stored contemporaneously when different images of the sequence have been displayed on the monitor one after the other. As an alternative it is also possible to provide said image sequence not to be displayed but only stored.

According to a further variant it is also possible to generate command sequences calling up and displaying different images both with respect to the section plane or the image plane and with respect to different image data sets from which images have to be produced. This command sequence can be stored and inputted as a command file in the system, which command file replaces manual selection controls like the shown joystick 5 and possible further devices alternative or provided in combination and which selection command file may comprise commands for storing the image sequence and/or for displaying images. These command files are indicated in FIG. 3 by the box 21 schematically representing an operative unit for generating, importing or storing one or more command file. Due to that, for example in the case when quick, preventive scans are made, so called pre-scan, it is possible to set predetermined image sequences and once they are automatically launched they collect different images of an image sequence that are an optimal travelling path for exploratory and approximately checking the presence of specific conditions, particularly specific pathologies.

When the MRI apparatus can be used for acquiring MRI images of different bodies under examination or different parts of said body under examination, particularly of different anatomical districts, it is possible for the system to be provided also with various command files each one comprising a selection command sequence composed of a different combination of subsequent commands selecting various images with regard to the image and/or section plane and/or with regard to the image data set, each one of said command file being possible to be called up and activated by the user for example by control means like buttons or the like and each one of said command files being univocally identified by a name or a logo.

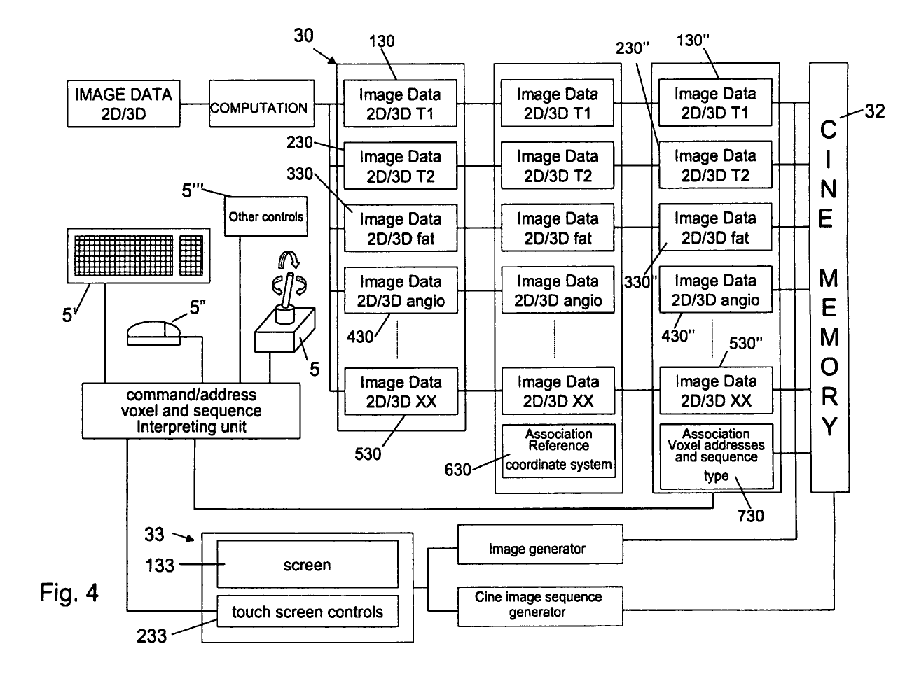

FIG. 4 shows a schematical example of an apparatus suited for operating the system described above with reference to FIG. 3.

The apparatus comprises a first memory 30, wherein image data of different data sets are stored in separated memory areas 130, 230, 330, 430 which can be addressed independently one from the other.

The memory area 530 shows that it is possible to provide further memory areas for further kinds of image data sets.

Data in memories 130, 230, 430 and 530 then are further associated to a univocal coordinate system as indicated by 630. Finally, on the basis of commands selecting and calling up the section or image plane and the image data set generated by means of an interpreting unit 31 by control means 5, 5′, 5″ 5′″ schematically representing a joystick, a keyboard, a mouse and other controls respectively the univocal recognizing indexes of voxels falling on the section or image plane that has been respectively selected are determined and said voxels, i.e. corresponding image data are taken from the memory area 130″, 230″, 330″, 430″ 530″ to corresponding addresses defined on the basis of identification codes of voxels. Thus image data regarding voxels falling on the selected section or image plane and from which the image displayed on the monitor is generated are send to the monitor.

By providing a CINE MEMORY memory 32 it is possible to store the image sequence and so to reproduce it as a cinematographic sequence.

In the case of a cinematographic sequence display it is possible also to provide means for changing the rate at which the image sequence is reproduced, or better to say the so called frame rate. Such change may be constant for the whole sequence time length or it may be different for different parts of the image sequence in order to extend or reduce reproduction times, i.e. the frame rate for some images of the sequence or for parts of said sequence.

Even in this case the system may be provided with means for controlling and changing the frame rate of the cinematographic sequence which means can be like the ones described for selecting section planes or kinds of image data sets.

Still with reference to FIG. 4, the monitor 33 may have a displaying area called screen and indicated by 133 and a touch-sensitive area 233 called touchscreen and at which it is possible to provide to display virtual buttons.

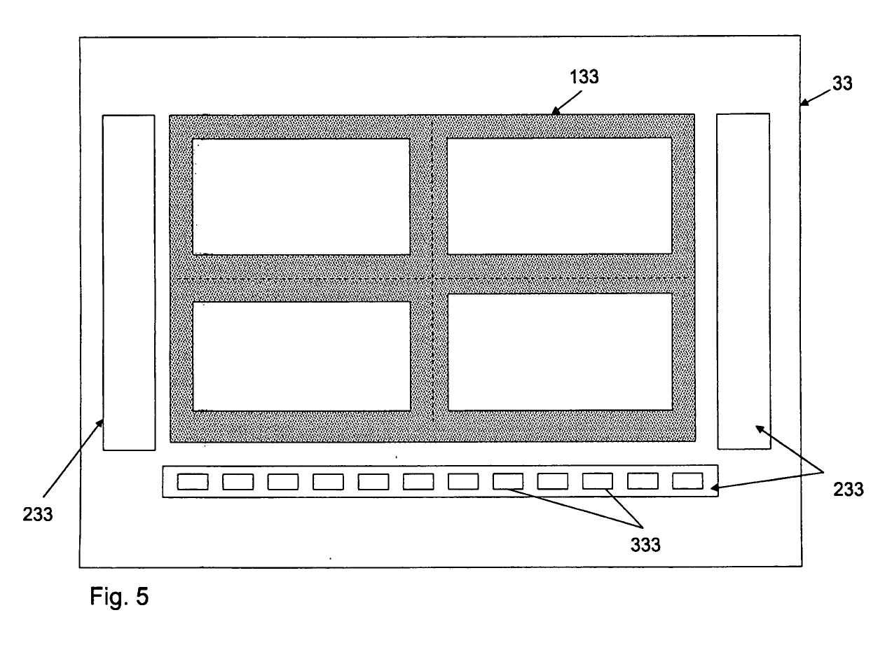

Finally FIG. 5 shows an example of a displaying monitor. In this example there are provided three areas for virtual button bars indicated by 233, whereas the central area 133 is the displaying screen. Buttons are shown only in the lower bar and are indicated by 333. When travelling depending on the specific displayed characteristics of the image, it is possible to display different virtual button bars allowing to activate specific processes or specific commands for the type of displayed image.

As regards the manufacturing point of view virtual button bars on touchscreen type screens are known both as regards hardware and software and are very popular for example in dispensers like automatic ticket dispensers or others.

Still with reference to FIG. 5 the displaying screen area may be divided in different regions. In the example said area is divided in four different areas, each one can be used to display different images or image sequences. So for example, it can be possible to display different images regarding the change in the sight direction and so in the section or image plane in an area, whereas in another area there are displayed different images regarding the change of the image data set used for the image along the current section plane that is displayed in the first area. A further area can display at the same time the cinematographic sequence of the exploratory preventive scan that can be used as a memo for the user for selecting the section or image plane and/or for selecting the type of image data set.

The fourth displaying area can be used for displaying alphanumeric data of interest or for displaying different images in editing a cinematographic sequence formed only of images selected among the ones displayed in different further areas.

This functionality is added to various further advantageous functionalities that the system and the apparatus according to the present invention allow to obtain and they have been previously described.

As described above when various image data sets are used, so it can be advantageous to provide a step registering said image data sets such that topologic references of voxels of individual image data sets with respect to the reference system are univocal for all image data sets.

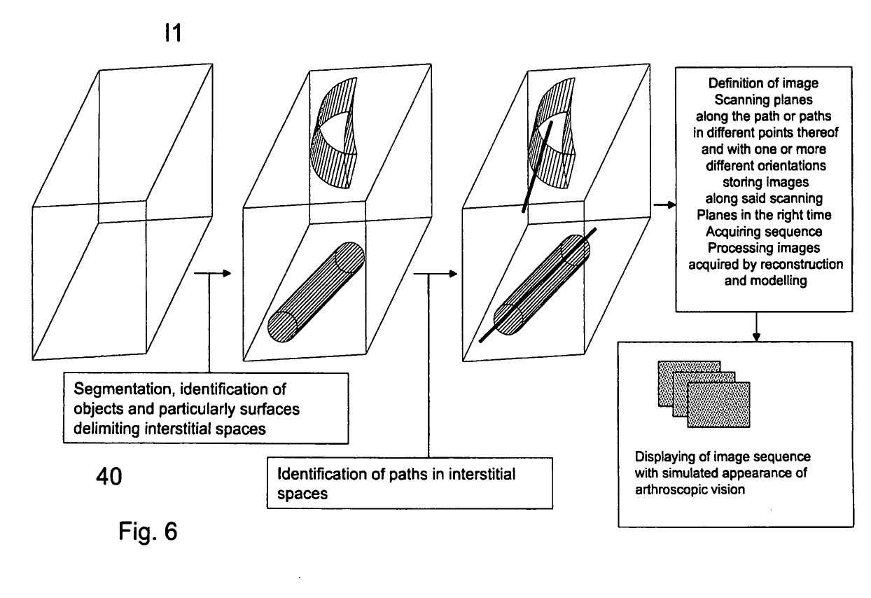

Referring to FIG. 6 there is shown a further improvement that can be obtained by the present invention.

The improvement that will be described aims at allowing to display image data and particularly for example a joint like the one of arthroscopy. The doctor carrying out said process as regards both surgical method and diagnosis being familiar with images of joint structures obtained in the typical target of said method, therefore such display would make more “user friendly” diagnostic images obtained by MRI and it would allow the optimal exchange of information between the radiologist carrying out the examination and the orthopedist, guaranteeing the greatest efficacy in treating the patient.

Substantially by using algorithms and processing methods the image data are processed in three-dimensional virtual scenes, wherein the user can travel by “moving” in interstitial spaces and by “watching” at surfaces of organs he meets in the path. This display follows the purely arthroscopic one, obtained by the orthopedist by inserting an optical visual probe inside the limb. The diagnosis can be supplemented by a film, reconstructed starting from MRI images, which film for example in the case of arthroscopy shows to the orthopedist the position of the pathology and it can be the optimal base for planning the operation.

Obviously even if there is a specific reference to the arthroscopy, it is possible to use said method for any kind of examination that can be carried out by an endoscope.

With particular reference to FIG. 6, starting from a three-dimensional image 11 acquired by conventional imaging MRI, the system provides means 40 for segmenting image data. The segmentation is a known technique and it is used in order to define subsets of image data, in this case of voxels belonging to the representation in the image of an object of the reproduced reality that as regards the physical appearance or other characteristics is a set. From segmented image data it is possible for example by means of image pattern recognition algorithms or other types of algorithms to generate the clustering of said pixel sets as virtual objects constituting a unit entity. In this case it is possible to reconstruct a virtual three-dimensional world by subjecting image data to a rendering and/or modelling processing. Thus the three-dimensional virtual scene is obtained having a univocal correlation with what is present in the real part reproduced by the image.

As regards the endoscopic or arthroscopic application that is the simulated displaying of image data likewise the vision obtained in a real endoscopic examination and particularly in an arthroscopic one, the objects that are recognized are interstitial spaces between individual organs or structures reproduced in the image and forming interstitial channels delimited by delimiting surfaces, such as shown by 41. Once the virtual three-dimensional scene has been generated it is possible to define a path P1 or P2 inside interstitial channels 41 by means 42. Along said paths P1 and P2 section planes along which two-dimensional images are detected or generated can be translated. At each point of the path the scanning plane may be oriented with different angles and it simulates a change of the sight angle of the reading head of the endoscope positioned at said. point of the path in the interstitial channel.

Images acquired along individual scanning planes provided along the path P1 or P2, are stored in accordance with the acquiring moment so they can be displayed in the right time succession and can give the impression of a film. Image data along each scanning plane are processed by means 43 that for example carry out again segmentations, modellings, reconstructions as what already said above and according to changing criteria of the displayed image similar to the vision by an endoscope and particularly a arthroscope. Finally the image sequence is displayed.

It is possible to provide to introduce signals or markers indicating the presence of particular conditions when the image of the image sequence wherein said condition is visible appears.

With particular reference to FIG. 5 the display simulating the endoscopic vision can be displayed on one of the displaying areas 133, whereas in other ones there can be proposed 2D images in the typical MRI tomograph vision corresponding to the image of the endoscopic type sequence that appears on the monitor in that moment.

It is to be noted that the displaying technique simulating the endoscopic vision has its best effect in the case of three-dimensional images, however it can be applied also to two-dimensional images. Moreover it is possible to combine such technique to one or more different modes for acquiring diagnostic images obtained by other kinds of apparati.

1. Method for displaying MRI images comprising:
displaying a plurality of different images one after the other obtained by nuclear magnetic resonance image acquisition, each of which image is different with respect to at least a part of the other images due to the fact that the plane of the displayed image corresponds to a different section plane through a body or part thereof under examination having a predetermined different position and/or a predetermined different orientation with respect to the body under examination and to a reference system;
wherein the passage from displaying an image to displaying a further image of the said plurality of images is achieved by control means generating command signals which define the parameter of the position and/or orientation of the different section planes of the different images of the said plurality of images

2. A method according to claim 1, wherein said control means are directional and/or pointing control means that can be angularly moved and/or translated with respect to a neutral or inactive or stand by reference position, like joystick, joypad, mouse or trackball, or the like.

3. A method according to claim 1, wherein said control means comprise selecting and activating means in the form of buttons or keys or combinations of keys of a keyboard.

4. A method according to claim 1, the control means define the parameter of each of the different images of the said plurality of images by means of signals for angularly moving or linearly displacing in one of various directions relatively to a starting reference position the section plane along which the image has to be displayed.

5. A method according to claim 1, wherein the said images of the said plurality of images are different one with respect to the others due to the fact that image data for generating at least a part of the said images are acquired with different modes or are obtained with different processing or computation methods with respect to image data of the rest of the images and the control means define the image to be displayed from the said plurality of images by means of signals for selecting and addressing and/or calling up image data from different image data sets each one of which sets corresponds to image data acquired or processed according to one of various different acquiring and/or processing modes.

6. A method according to claim 1, further comprising providing separated control means for displaying different images with regards to the position and orientation of the section plane along which the image is generated and a separated control means for displaying different images with regards to the mode acquiring and/or processing image data.

7. A method according to claim 1, wherein said control means include control means with a directional control member whose movement is correlated to a predetermined forward and/or pointing direction, which direction corresponds to a watching direction or a direction of view, the section or image plane being defined with a predetermined position and orientation with respect to said watching direction.

8. A method according to claim 1 further comprising:
acquiring by means of a MRI scanner at least a two-dimensional MRI image according to at least a section plane of a body or a part of the body to be examined and displaying said MRI image;
defining at least a reference position and a reference direction having a predetermined orientation with respect to said MRI image and displaying said direction on the MRI image displayed at the previous step;
defining a movement of displacement of the section plane along a direction having a predetermined orientation with respect to said at least one reference position and to the said reference direction;
acquiring and displaying one or more further MRI images along section planes translated and/or rotated with respect to the section plane of a first MRI image or of a preceding MRI image according to said at least one direction of displacement of the section plane.
and wherein the selecting command is generated by commands of displacing by translation of the section plane forward or backward with reference to a reference section plane and/or commands rotating the section plane forward and backward with respect to a predetermined reference section plane, which commands are generated and inputted by directional control interface means.

9. A method according to claim 8, further comprising setting a minimum step for moving and/or rotating the section plane with respect to a reference plane, each operation of button a means and/or each pivotal movement and/or rotation of a lever of a joystick being associated to forward or backward movement and/or to the rotation in one direction or in the opposite direction only of a step of the section plane with respect to the section reference plane

10. A method according to claim 9, wherein the repeated operation of the button means and/or of the lever of the joystick causes the forward and/or backward movement and/or the rotation in one direction and in the other one of a further step of the section plane.

11. A method according to claim 8, further comprising providing for a continuous operation, such as the continuous pushing of a button and/or the continuous pivotal movement of a lever of a joystick, which determines a sequence of forward and/or backward movement steps or rotation steps in one direction or in the other one.

12. A method according to claim 8, wherein in combination with a joystick it provides to correlate the tilt angle of the joystick with respect to a neutral position to a scale of forward and/or backward and/or rotating movement in one direction or in the other one of the section plane.

13. A method according to claim 8, wherein it provides the acquisition of three dimensional image data of a body or part thereof, a reference system being associated to three-dimensional image data and the displayed image being the one defined by two dimensional image data falling or coinciding with a virtually defined section plane of the three-dimensional set of image data which virtual section plane has a position and orientation with respect to said three-dimensional set of image data corresponding to the position and the orientation of a desired section plane of the body under examination or part thereof reproduced by said three-dimensional set of image data.

14. A method according to claim 13, wherein on the monitor one or more reference two-dimensional images along one or more different section plane of the three-dimensional image are displayed in combination with the reference coordinate system and in combination with the image of the line intersecting the selected section plane with the one or more reference section planes.

15. A method according to claim 14, wherein for each change of the position of the section plane both as regards a translation and as regards a rotation the section line of the selected section plane with one or more reference section planes and/or the image of said new section plane with the new position and the new orientation with reference to the reference three-dimensional image and also the translation direction or the rotation direction of the changing step from the preceding selected section plane to the present one is displayed.

16. A method according to claim 14, wherein in case of rotation of the selected section plane both the last image regarding the section plane in the first angular position and the current image along then section plane with the second angular position are displayed.

17. A method according to claim 14, wherein at least three screens are provided one being in a central position between two lateral screens, the central screen being the one on which the images on different section planes perpendicular to a defined direction of displacement or of forward or rearward navigation are displayed, while on the two lateral screens which are oriented at an angle with respect to the central screen and symmetrically relatively to a centre section plane perpendicular to the said central screen images are displayed along section planes whose angle relatively to the section plane of the image displayed on the central screen corresponds to the angle of corresponding the lateral screen relatively to the central screen.

18. A method according to claim 8, wherein it provides to carry out an exploratory preventive scan with scanning sequences, that is with parameters acquiring image data set such that to reduce time for acquiring and generating the image, the said exploratory preventive scan provides to acquire three-dimensional images of a body under examination or a part thereof, and to virtually travel inside said volumetric image, generating two-dimensional image views that a virtual person would have by turning his eyes in a predetermined direction inside the three-dimensional virtual image, whereas it has means for identifying regions of the body under examination corresponding to partial regions of the whole three-dimensional image for which image data acquisition are made with different scanning sequences set for acquiring high quality images.

19. A method according to claim 5, wherein for the same body part it provides a plurality of image data acquired according to different modes i.e. according to different settings of acquiring parameters or of so called acquiring or scanning sequences and by which different characteristics of the body under examination, particularly of tissues thereof are highlighted.

20. A method according to claim 5, wherein it provides to determine different image data sets from at least a single image data set acquired at the beginning according to a predetermined acquiring mode by means of operations computing or mathematically processing image data acquired at the beginning.

21. A method according to claim 20, wherein by control means it determines the passage from the image along a predetermined section plane relevant to image data acquired according to a predetermined mode or obtained by a predetermined computation or processing method to one or more subsequent images along the same section plane and relevant to image data acquired according to one or more further acquiring modes or one or more further modes for computing or processing image data.

22. A method according to claim 21, wherein it provides to acquire three-dimensional or two-dimensional images of the same body under examination, with different kinds of acquiring sequences that are the sequences called as T1, T2, fat suppression, angio, and the alternative display on a monitor of the image relevant to the same section plane, with reference to the acquired three-dimensional image or with reference to a plurality of two-dimensional images acquired with said different sequences.

23. A method according to claim 19, further comprising:
a) generating by computation from three-dimensional or two-dimensional image data obtained by at least a single scan a plurality of different image data sets or acquiring a plurality of different image data sets each one by a scan with a different scanning sequence;
b) storing said image data each one in a dedicated memory or in a dedicated memory area;
c) associating an identification code to each image datum of each image data set;
d) associating an identification code to each image data set computed or acquired with a different scanning sequence;
generating a command for calling up from the corresponding memory or memory area a single image datum and/or image data along a predetermined image plane and for displaying on a monitor the called up image datum or image data, which command comprises a univocal identification code of the memory area wherein the image data set is stored from which the image datum or data are called up and an univocal identification code of the image datum or data within said image data set;
generating one or more different call-up commands one after the other for calling up from the same memory area or from different memory areas a single image datum and/or image data along the same predetermined image plane or along a different image plane and for displaying on a monitor the image datum or image data called up with each subsequent command, which command comprises a univocal identification code of the memory area wherein each different respective image data set is stored from which the image datum or data are called up and a univocal identification code of the image datum or data within each one of said image data sets.

24. A method according to claim 23, wherein it provides the storage according to the right time succession of all images displayed along different section planes selected during the traveling i.e. the navigation process and/or all images corresponding to image data processed according to different modes for processing resonance signals and/or obtained by different acquiring modes said stored image sequence can be called up and displayed in the right image time succession.

25. A method according to claim 1, wherein image data of each acquired image are transformed as regards the visual appearance of the corresponding displayed image in a view like the one occurring by using an endoscopic instrument.

26. A method according to claim 25, wherein it provides means segmenting the image along each section plane and recognizing subsets of image data representing anatomical and/or functional objects;
means recognizing anatomical and/or functional objects represented by said subsets of image data;
means identifying objects represented in images and composed of interstitial space image;
means determining three-dimensional surfaces from data of surfaces or lines delimiting interstitial spaces determined in each one of a plurality of images obtained along different scanning planes each one having a predetermined different position and/or predetermined different orientation with respect to scanning planes of the remaining other images.
means indicating if the passage from the image plane of an image to the image plane of a subsequent image follows the path of an interstitial space as regards direction and/or length.

27. A method according to claim 26, it provides means acquiring at least a three-dimensional image of an anatomical district by acquiring image data inside a three-dimensional area of a body under examination, said three-dimensional image being subjected to segmentation and recognition of subsets of image data representing interstitial spaces and/or surfaces delimiting thereof and movement paths of scanning planes of three-dimensional images being generated going along interstitial channels delimited by said surfaces, there being possible to orient the scanning plane passing through a predetermined point along said movement path according to any direction with respect to the path axis at said point.

28. A method according to claim 27, wherein surfaces delimiting interstitial spaces are surfaces represented in acquired image delimiting structures or organs.

29. A method according to claim 27, wherein it comprises means for virtually extended distances between opposite surfaces delimiting interstitial spaces, which means are for example a virtual zoom.

30. A method according to claim 27, wherein it comprises steps segmenting the virtual image or images, determining objects represented by subsets of image data and particularly surfaces delimiting interstitial spaces on the basis of the segmentation of the image, reconstructing virtual images from image data segmented by modeling and rendering; determining communicating interstitial passages and determining passing path or paths through said interstitial paths; determining a sequence of scanning plane along a predetermined path for forward and/or backward movement of an image scanning plane along one or more of said paths; determining one or more predetermined scanning planes having one or more different orientations with respect to a point on said movement path of the scanning plane, generating the virtual image reconstructed by rendering and/or modelling along each section plane and putting said images according to a predetermined acquiring time order and simulating a natural forward movement of a real endoscopic probe inside an interstitial passage, storing said image sequence and displaying the image sequence as a film such to simulate vision modes of an endoscopic instrument and particularly by arthroscopy.

31. A method according to claim 27, wherein it comprises means for smoothing surfaces delimiting interstitial channels.

32. Apparatus for acquiring and displaying MRI images and having means for acquiring and generating image data, at least a memory for storing image data; means for selecting a section plane along which a MRI image can be acquired and displayed and means for displaying said MRI image along said section plane, wherein said means for selecting and changing the section plane along which the MRI image is acquired are composed of one or more buttons for commanding the translation in the forward direction and in the opposite backward direction and/or one or more buttons for commanding the rotation of the section plane in one direction and in the opposite direction.

33. Apparatus according to claim 32, wherein alternatively or in combination said selecting means may be a joystick, a joypad, a trackball, a mouse, a keyboard or the like.

34. Apparatus according to claim 32, wherein said means for selecting and changing the section plane have means for interfacing the command moving forward and/or backward and/or rotating the section plane in one direction or in the opposite one to units setting the imaging section plane of the MRI scanner.

35. Apparatus according to claim 32, wherein it comprises a plurality of means for acquiring magnetic resonance signals according to different acquiring modes, particularly according to different sequences acquiring magnetic resonance signals, and/or different means for generating image data from magnetic resonance signals according to different modes processing said magnetic resonance signals;
means for separately storing each set of magnetic resonance signals or each image data set obtained by each one of the different modes acquiring magnetic resonance signals and/or according to each of the different modes processing said magnetic resonance signals;
means for univocally identifying said sets of magnetic resonance signals or said image data sets;
means for selecting one of said different sets of magnetic resonance signals and/or said different image data sets;
commands means for calling up from the corresponding memory and for displaying the selected set of magnetic resonance signals or image data set;
means for changing the selection of the set of resonance magnetic signals or the image data set being provided.

36. Apparatus according to claim 35, wherein said selecting means, said call up command means and said means for changing the selection of a predetermined set of magnetic resonance signals and/or a predetermined image data set are provided in combination with selecting means, means for changing the selection of a section plane along which an MRI image can be acquired and display.

37. Apparatus according to claim 32, wherein the means for acquiring and generating image data has means for acquiring three-dimensional images whose image data describing the appearance of each voxel of the three-dimensional image are stored in a memory, means for selecting the section plane and for changing it being provided with means interfacing a reading unit for image data relevant to voxels of the three-dimensional image that coincide with a virtual section plane of the three-dimensional image within a predetermined tolerance.

38. Apparatus according to claim 37, wherein the reading unit manages the access to memory addresses of image data of individual voxels in a way corresponding to topographic relations between individual voxels.
